(19) United States
(12) Patent Application Publication
(10) Pub. No.: US 2021/0404079 A1
(43) Pub. Date: Dec. 30, 2021

(54) Manufacture Method of Mask for Evaporation and Mask for Evaporation

(71) Applicant: BOE Technology Group Co., Ltd., Beijing (CN)

(72) Inventors: Zhihui Xiao, Beijing (CN); Yuanzheng Guo, Beijing (CN); Feifei Wang, Beijing (CN)

(73) Assignee: BOE Technology Group Co., Ltd., Beijing (CN)

(21) Appl. No.: 16/490,385

(22) PCT Filed: Mar. 6, 2019
(86) PCT No.: PCT/CN2019/077200

§ 371 Date: Aug. 30, 2019

(30) Foreign Application Priority Data
May 31, 2018 (CN) 201810547816.4

(51) Int. Cl. C25D 1/10; C23C 14/04; C23C 14/24

(52) U.S. Cl. CPC C25D 1/10; C23C 14/24; C23C 14/042

(57) ABSTRACT

The present disclosure provides a manufacture method of a mask for evaporation and a mask. The manufacture method of a mask for evaporation includes: providing an open mask the open mask including at least one open region (BB); forming a photoresist layer at least in the at least one open region, at least a portion of a pattern of the photoresist layer in the open region (BB) being identical to a hollow portion pattern of the mask for evaporation; and depositing a material of the mask for evaporation in a region in which the photoresist layer is formed, so as to form the non-hollow portion pattern of the mask for evaporation, in which the non-hollow portion pattern is connected to a side wall of the open region at an edge of the non-hollow portion pattern.

### TECHNICAL FIELD

The present disclosure relates to a manufacture method of a mask for evaporation and a mask for evaporation.

### BACKGROUND

OLED display panels are called as the most promising display devices because of characteristics of self-illumination, high brightness, high contrast, low operating voltage, capability of flexible display, and so on. As self-illumination display devices, in order to improve display color gamut, contrast and brightness efficiency, the OLED display panels generally use independent sub-pixel light emitting layers to realize color display. For example, the red (R) color sub-pixel adopts a light emitting layer capable of emitting red light, the green (G) color sub-pixel adopts a light emitting layer capable of emitting green light, and the blue (B) color sub-pixel adopts a light emitting layer capable of emitting blue light.

FMM (Fine Metal Mask) is required for evaporating the independent sub-pixel light emitting layers. The quality of the FMM, such as the force uniformity of the FMM, the positional accuracy of the grid structure, and so on, directly determines the evaporation quality of the light emitting layers, and further affects the display effect. Therefore, it is critical to improve the quality of the FMM for improving the quality of the display panel.

### SUMMARY

Embodiments of the present disclosure provide a manufacture method of a mask for evaporation and a mask for evaporation, so as to improve the quality of the mask for evaporation.

At a first aspect, an embodiment of the present disclosure provides a manufacture method of a mask for evaporation, the manufacture method comprises: providing an open mask, the open mask comprising at least one open region; forming a photoresist layer at least in the at least one open region, at least a portion of a pattern of the photoresist layer in the open region being identical to a hollow portion pattern of the mask for evaporation; and depositing a material of the mask for evaporation in the open region in which the photoresist layer is formed, so as to form a non-hollow portion pattern of the mask for evaporation, wherein the non-hollow portion pattern is connected to a side wall of the open region at an edge of the non-hollow portion pattern.

Optionally, the manufacture method further comprises: removing the photoresist layer, so as to obtain the mask for evaporation comprising the non-hollow portion pattern.

Optionally, depositing of the material of the mask for evaporation on a side of the open mask in which the photoresist layer is formed comprises: depositing the material of the mask for evaporation by an electroforming deposition process.

Optionally, the forming of the photoresist layer in the at least one open region comprises: coating a photoresist in the at least one open region; and patterning the photoresist to remove the photoresist at a line position of the non-hollow portion pattern.

Optionally, an area of the non-hollow portion pattern of the mask for evaporation is smaller than an area of the open region.

Optionally, the manufacture method further comprises: further removing at least a portion of the photoresist between the edge of the non-hollow portion pattern and the side wall of the open region while removing the photoresist at the line position of the non-hollow portion pattern, so that a gap is formed between the at least a portion of the edge of the non-hollow portion pattern and the side wall of the open region.

Optionally, the further removing of at least a portion of the photoresist between the edge of the non-hollow portion pattern and the side wall of the open region while removing the photoresist at the line position of the non-hollow portion pattern comprises: removing an annular photoresist between the edge of the non-hollow portion pattern and the side wall of the open region, so that a gap is formed between the edge of the non-hollow portion pattern and the side wall of the open region.

Optionally, a thickness of the photoresist layer is equal to a thickness of the open mask; or a thickness of the photoresist layer is smaller than a thickness of the open mask, and one surface of the photoresist layer is flush with one surface of the open mask.

Optionally, the photoresist layer further covers a non-open region of the open mask.

Optionally, before the forming of a photoresist layer in the at least one open region, the method comprises: placing the open mask on a base, so as to allow the base to support the open region.

Optionally, the non-hollow portion pattern of the mask for evaporation is a grid structure comprising horizontally and vertically intersecting lines.

Optionally, under a condition that the photoresist layer is formed only in the at least one open region, the depositing of a material of the mask for evaporation in a region in which the photoresist layer is formed comprises: blocking the non-open region, so as to deposit the material of the mask for evaporation in the region in which the photoresist layer is formed.

On a second aspect, embodiments of the present disclosure provide a mask for evaporation, the mask for evaporation is manufactured by the manufacture method according to the first aspect, and the mask for evaporation comprises: an open mask comprising at least one open region; and at least one non-hollow portion pattern of the mask for evaporation. The at least one non-hollow portion pattern of the mask for evaporation is in the at least one open region in a one-to-one correspondence, and the non-hollow portion pattern is connected to a side wall of the open region in which the non-hollow portion pattern is located at an edge position of the non-hollow portion pattern.

Optionally, an area of the non-hollow portion pattern of the mask for evaporation is smaller than an area of the open region.

Optionally, a connection structure is disposed between at least a portion of the edge of the non-hollow portion pattern of the mask for evaporation and the side wall of the open region, and the connection structure connects the edge of the non-hollow portion pattern of the mask for evaporation and the side wall of the open region.

Optionally, an annular connection structure is disposed between the edge of the non-hollow portion pattern of the mask for evaporation and the side wall of the open region, the annular connection structure is around the non-hollow portion pattern of the mask for evaporation.

Optionally, a width of the connection structure ranges from 0.1 mm to 20 mm.

Optionally, materials of the open mask, the non-hollow portion pattern, and the connection structure comprise invar and/or metal nickel.

Optionally, thicknesses of the non-hollow portion pattern and the connection structure are equal to or smaller than a thickness of the open mask.

Optionally, the non-hollow portion pattern of the mask for evaporation is a grid structure comprising horizontally and vertically intersecting lines.

Optionally, the mask for evaporation further comprises: a support frame at a side of the open mask, the support frame being in contact with a side of the open mask, so as to support the open mask.

Optionally, the open mask, the connection structure, and the non-hollow portion pattern of the mask for evaporation form as an integrated structure.

### BRIEF DESCRIPTION OF THE DRAWINGS

The above and/or additional aspects and advantages of the present disclosure will be apparent and easily understood by the following descriptions of the embodiments in combination with the figures.

FIGS. 1a-1d are schematic diagrams of an exemplary tensioning process of an FMM;

FIGS. 2a-2e are step diagrams of a manufacture method of a mask for evaporation provided by embodiments of the present disclosure;

FIGS. 3a-3e are sectional structure diagrams respectively of the FIGS. 2a-2e along a dotted line aa′.

Reference numerals:

| | |
|---|---|
| 1-metal frame; | 2- cover; |
| 3- howling; | 4- FFM unit; |
| AA- display region; | 5- open mask; |
| 51- jig groove; | BB- open region; |
| 6- photoresist; | 6′ - photoresist layer; |
| 7′- hollow portion pattern of a photoresist layer; | d- gap; |
| 7- non-hollow portion pattern of a mask for | |
| evaporation; | |
| 8- connection structure | |
| 9- base; | 10- nozzle; |
| 11-support frame; | |
| CC- a region where non-hollow portion pattern is | |
| located. | |

### DETAILED DESCRIPTION

The embodiments of the present disclosure are described in detail below, and the examples of the embodiments are illustrated in the accompanying drawings, in which the same or similar reference numerals are used to refer to the same or similar components or components having the same or similar functions. The embodiments described below with reference to the accompanying drawings are exemplary, and are only used for illustrating the present disclosure and are not to be construed as limiting of the present disclosure.

In order to make the above objects, features and advantages of the present disclosure be understood more clearly, technical solutions of the embodiments of the present disclosure are described clearly and completely with reference to the accompanying drawings. It is apparent that the described embodiments are only a part of the embodiments of the present disclosure, and not all the embodiments. All other embodiments obtained by a person of ordinary skill in the art based on the embodiments of the present disclosure without creative work are within the scope of the present disclosure.

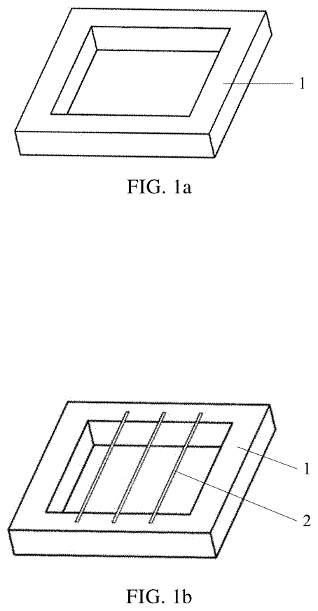

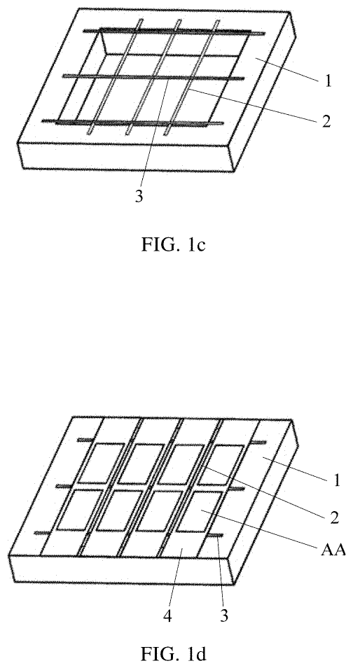

The quality of the FMM, such as the force uniformity of the FMM, the positional accuracy of the grid structure, and so on, directly determines the evaporation quality of light emitting layers. As illustrated in FIGS. 1a-1d, a manufacture method of the FMM roughly comprises: sequentially welding a cover 2, a howling 3, and a strip-shaped FMM unit 4 having a grid structure on a metal frame 1, to form a set of FMM. The step of welding the FMM unit 4 is called as a tensioning process, and the tensioning process is actually a process of spreading and tightening the FMM unit 4.

With the improvement of the display panel PPI (Pixels Per Inch, the number of pixels per inch) and the development of the special-shaped display panel, in the process of manufacturing a high PPI FMM or a special-shaped FMM, the FMM is prone to the problem of uneven force in the tensioning process, which causes a display region AA of the FMM to be wrinkled, resulting in problems of color mixing of the evaporated light emitting layers of different colors. Especially for the special-shaped display panel, for example, a display panel with four rounded corners, or other irregularly shaped display panels, because of the irregular shapes, the display region of the FMM is more prone to be wrinkled.

For example, the manufacture of the FMM for the special-shaped display panels usually adopts the following two methods:

Method 1: Where an FMM unit is manufactured, a dummy structure that is not etched or that is half-etched is formed in a region where rounded corners are required or irregular patterns are formed. The production cost of this method is relatively high, and because of the existence of irregular structures, there is stress difference in different positions of the FMM unit during the tensioning process, and the difficulty of the tensioning process is increased. With the improvement of the pixel resolution, the requirements of the pixel positional accuracy (PPA) are getting higher and higher, and it is very easy to cause problems such as color mixing or the like.

Method 2: The outer contour of the desired special-shaped display panel is formed by the blocking of the cover 2 and the howling 3 in the FMM. This method highly requires the positional accuracy of the display panel, and is also prone to cause problems such as color mixing and the like.

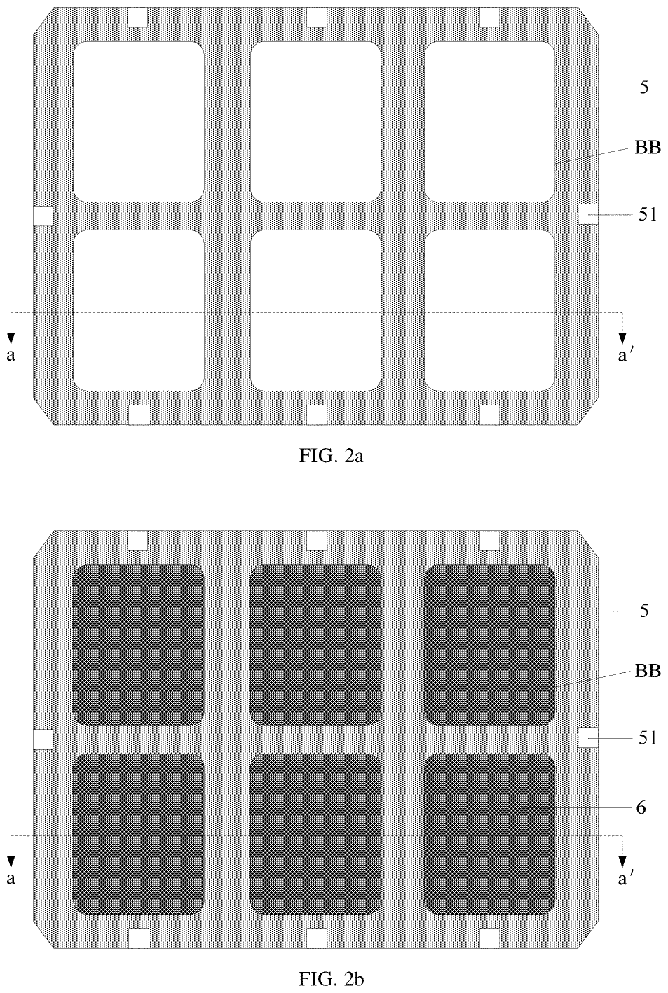

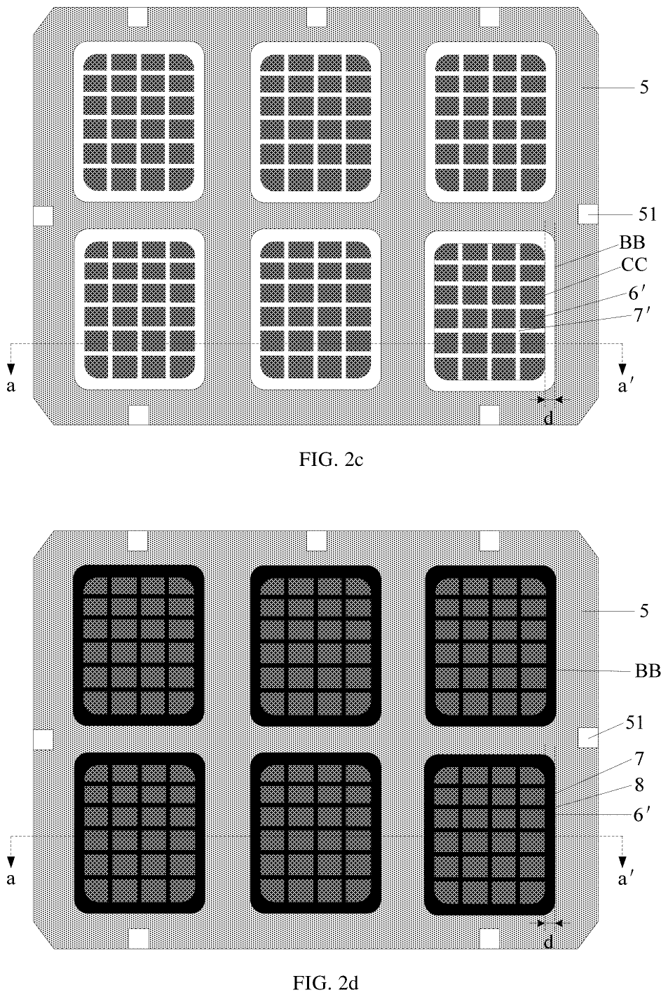

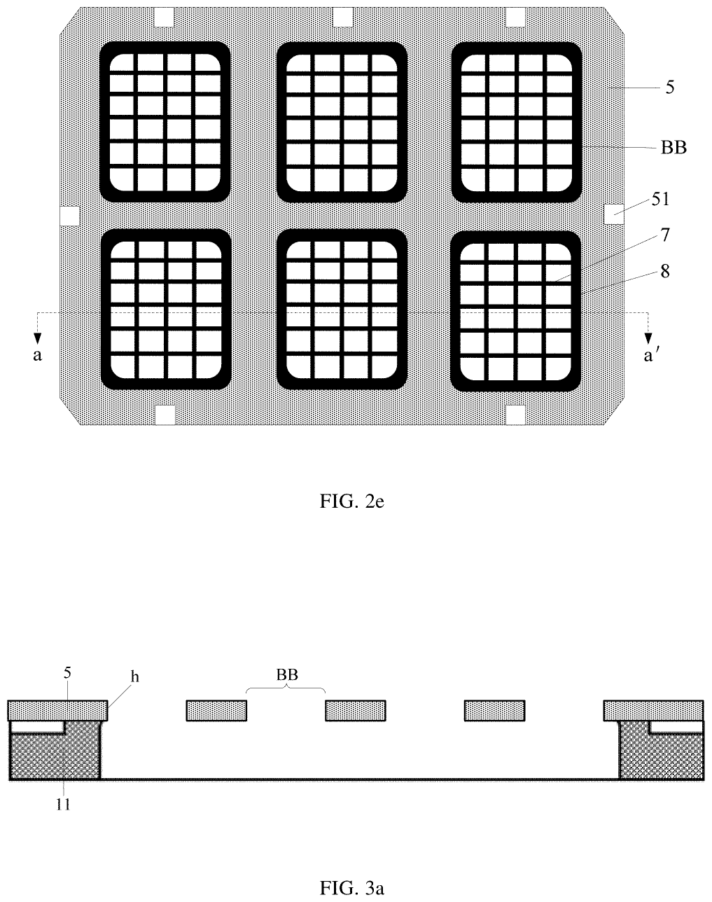

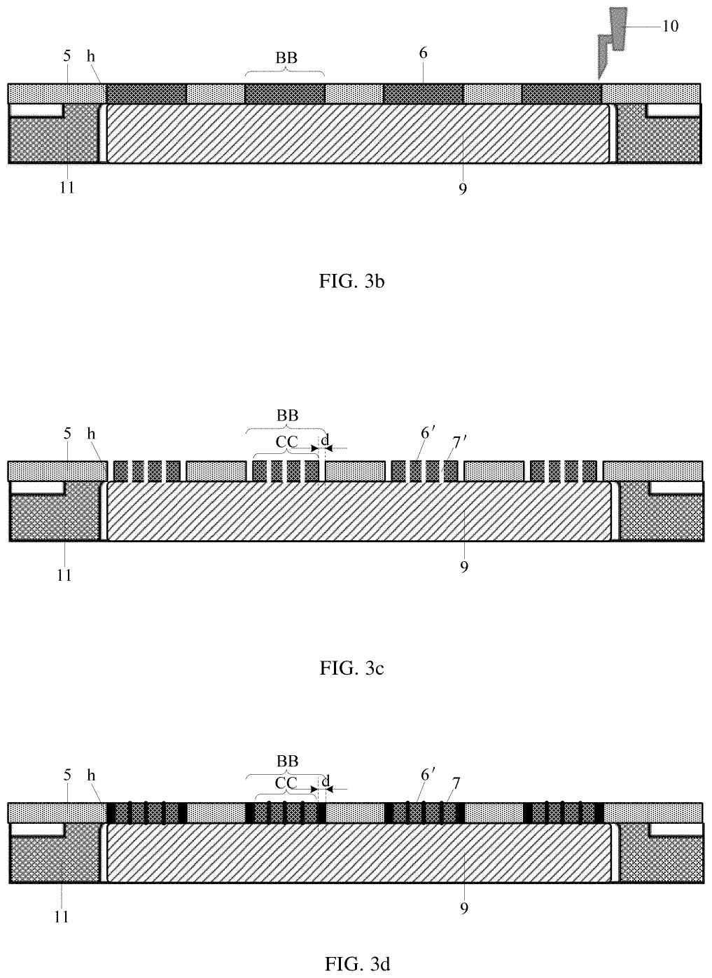

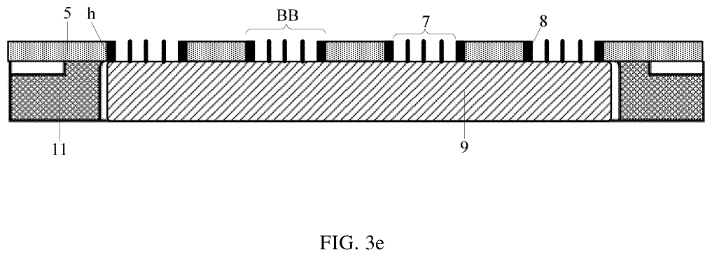

An embodiment of the present disclosure provides a manufacture method of a mask for evaporation. As illustrated in FIG. 2a to FIG. 2e and FIG. 3a to FIG. 3e, the manufacture method comprises the following steps:

S1: referring to FIG. 2a and FIG. 3a, providing an open mask 5, the open mask 5 comprises at least one open region BB.

A size and an area of the open region BB of the open mask 5 may be equal to or slightly larger than an overall size and area of a non-hollow portion pattern, such as the grid structure, of the mask for evaporation to be formed. A material of the open mask 5 may be a material of the mask used for performing an evaporation process for light emitting layers, and may be, for example, invar, metal nickel (Ni) or the like.

Edges of the open mask 5 are provided with a plurality of jig grooves 51.

Where the mask for evaporation comprising the open mask 5 performs an evaporation process, a jig will clamps edges of a substrate to be evaporated, so that the substrate to be evaporated is attached to the open mask. The jig grooves 51 can accommodate the jig clamping the edges of the substrate to be evaporated, and allow the substrate to be evaporated to be closely attached to the open mask.

A lower surface of the open mask 5 (a surface of the open mask 5 that is attached to the substrate to be evaporated is an upper surface, and a surface opposite to the upper surface is the lower surface) may further be provided with a support frame 11, the support frame 11 is connected with edges of the lower surface of the open mask 5 to support the open mask 5.

S2: referring to FIG. 2b, FIG. 2c, FIG. 3b and FIG. 3c, forming a photoresist layer 6′ at least in each open region BB of the open mask 5. In each open region, a pattern of the photoresist layer 6′ at least comprises a hollow portion pattern 7′ of the photoresist layer which is identical to the non-hollow portion pattern of the mask for evaporation.

For example, the above step S2 may comprise:

S21: coating a photoresist 6 in the open region BB of the open mask 5, as illustrated in FIG. 2b and FIG. 3b.

During coating, a nozzle 10 may be used to coat the photoresist only in the open region BB, or coat the photoresist on both the open region BB and a non-open region of the open mask 5, so that the nozzle 10 can coat the photoresist continuously, this operation is more convenient, and the photoresist on the non-open region of the open mask 5 also blocks the material of the mask for evaporation which is deposited in the subsequent step, thereby preventing the material of the mask for evaporation from being deposited on the non-open region of the open mask. In addition, the photoresist in the non-open region only needs to be removed after the non-hollow portion pattern, such as a grid structure, of the mask for evaporation is formed, and does not affect the forming of the non-hollow portion pattern, such as the grid structure.

S22: patterning the photoresist 6, removing the photoresist at the non-hollow portion pattern, for example, at a line position of the grid structure, so as to obtain a photoresist layer 6′ comprising a hollow portion pattern 7′ corresponding to the non-hollow portion pattern of the mask for evaporation, as illustrated in FIG. 2c and FIG. 3c.

The step of patterning the photoresist 6 may comprise the steps of exposing and developing the photoresist 6. Continuing to refer to FIG. 2c and FIG. 3c, while removing the photoresist at the non-hollow portion pattern, for example, at the line position of the grid structure, at least a portion of the photoresist between an edge of the non-hollow portion pattern and a side wall of the opening is removed, so that there may be a gap between an edge of the non-hollow portion pattern and the side wall of the open region. For example, an annular photoresist between the edge of the non-hollow portion pattern and the side wall of the opening is simultaneously removed, so that there is a gap between the entire edge of the non-hollow portion pattern of the mask for evaporation obtained finally and the side wall of the open region. Thus, an area of the hollow portion pattern 7′ of the photoresist layer which is formed is smaller than an area of the open region BB, and there is a gap d between at least a portion of the edge of the hollow portion pattern 7′ of the photoresist layer and the side wall h of the open region BB. The figure illustrates that there is a gap d between the entire edge of the hollow portion pattern 7′ of the photoresist layer and the side wall h of the open region BB, which enables the material of the mask for evaporation to be deposited in the gap d in the subsequent step, so as to form a connection structure connecting the edge of the non-hollow portion pattern and the side wall. For example, an annular connection structure, that is, a ring structure, surrounding the non-hollow portion pattern of the mask for evaporation is formed between the non-hollow portion pattern of the mask for evaporation and the side wall of the opening, so that the non-hollow portion pattern, such as a grid structure, of the formed mask for evaporation is connected with the side wall h of the open region BB through the connection structure, such as the ring structure, so that the force applied on the non-hollow portion pattern, such as the grid structure, of the formed mask for evaporation, is more uniform.

It should be noted that, the “edge of the hollow portion pattern 7′ of the photoresist layer (corresponding to the non-hollow portion pattern 7 of the mask for evaporation)” in the present embodiment specifically refers to the edges of the complete continuous region corresponding to the non-hollow portion pattern 7 of the mask for evaporation. The continuous region is indicated by CC in FIG. 2c and FIG. 3c. It can be clearly seen from the figure that a shape of the pattern region CC of the grid structure is substantially the same as a shape of the open region BB, a size of the pattern region CC of the grid structure is smaller than a size of the open region BB, and there is a gap d between the edge of the pattern region CC of the grid structure and the side wall h of the open region BB.

For example, at least a portion of edges of the non-hollow portion pattern of the mask for evaporation may be connected to the side wall of the open region through the connection structure, and the remaining edges are connected to the side wall of the open region by the non-hollow portion pattern of the mask for evaporation itself. Alternatively, all the non-hollow portion pattern of the mask for evaporation is connected to the side wall of the open region through the connection structure, and the embodiments of the present disclosure is not limited thereto, as long as the pattern of the mask for evaporation can be stably supported.

In the above step S2, in order to facilitate the coating operation of the photoresist 6, the open mask 5 may be placed on a base 9 before the photoresist 6 is coated, and the base 9 supports the open region BB of the open mask 5.

Moreover, in the above step S2, a thickness of the formed photoresist layer 6′ actually determines a thickness of the non-hollow portion pattern, such as a thickness of the grid structure, of the mask for evaporation subsequently formed, therefore, the thickness of the formed photoresist layer 6′ may be set according to the need for the thickness of the pattern, for example, the grid structure. Illustratively, a thickness of the photoresist layer 6′ is equal to a thickness of the open mask 5, so that the thickness of the subsequently formed non-hollow portion pattern, such as the thickness of the grid structure, of the mask for evaporation can be equal to the thickness of the open mask 5; or the thickness of the photoresist layer 6′ is smaller than the thickness of the open mask 5, and one surface of the photoresist layer 6′ is flush with one surface of the open mask 5, for example, a surface of the photoresist layer 6′ away from the base 9 is flush with a surface of the open mask 5 away from the base 9, so that a surface of the grid structure of the mask for evaporation subsequently formed is flush with the surface of the open mask 5, which ensures that the grid structure and the open mask 5 can be closely attached to the substrate to be evaporated during the evaporation process. Further illustratively, the thickness of the photoresist layer 6′ may specifically range from 5 μm to 30 μm.

It should be noted that, in the case where the thickness of the photoresist layer 6′ is smaller than the thickness of the open mask 5, when the photoresist layer 6′ is formed, a position of the base 9 corresponding to the open region BB may be provided with a protrusion, and a height of the protrusion is equal to a thickness difference between the open mask 5 and the photoresist layer 6′ to be formed, so that the formation of the photoresist layer 6′ with a desired thickness can be achieved.

In addition, the “thickness” in the present embodiment refers to a size of a corresponding component or object in a direction perpendicular to a plane in which the open mask 5 is located.

S3: referring to FIG. 2d and FIG. 3d, a material of the mask for evaporation is deposited in a region where the photoresist layer is formed, so as to form a non-hollow portion pattern of the mask for evaporation. The non-hollow portion pattern is connected to the side wall of the open region at an edge of the non-hollow portion pattern. For example, the photoresist layer 6′ is used as a mask to deposit the material of the non-hollow portion pattern, such as a grid structure, of the mask for evaporation in the open region BB, so as to form the non-hollow portion pattern, such as a grid structure 7, of the mask for evaporation. For example, the edge of the non-hollow portion pattern, such as a grid structure 7, and the side wall h of the open region BB in which the non-hollow portion pattern is located are connected to form an integrated structure.

In the above steps, the material of the non-hollow portion pattern, such as the material of the grid structure, of the mask for evaporation may be deposited in the open region BB by using an electroforming deposition process. Exemplarily, during the electroforming deposition process, the open mask 5, the photoresist layer 6′, the support frame 11, and the base 9 under the open mask 5 are all put into an electroforming solution to perform the electroforming deposition process. After the electroforming deposition process is completed, the base 9 is raised, and the open mask 5, the photoresist layer 6′, and the support frame 11 are moved out from the electroforming solution. The thickness of the deposited non-hollow portion pattern, for example, the thickness of the grid structure 7 may be the same as the thickness of the photoresist layer 6′.

In the above steps, because the non-hollow portion pattern, such as the grid structure 7, is naturally formed in the open region BB by the electroforming deposition process, the grid structure 7 is naturally connected to the side wall h of the open region BB to form an integral structure. Compared with the grid structure of the FFM units formed by the tensioning process, the force uniformity on the naturally formed non-hollow portion pattern, such as the grid structure 7, in the present embodiment, is greatly improved, and no wrinkle is generated in a display region of the mask for evaporation, or the wrinkle is alleviated, and the pixel positional accuracy of the non-hollow portion pattern, such as the grid structure, of the mask for evaporation is improved, and the quality of the mask for evaporation is improved, which is beneficial to the quality of the evaporated light emitting layer. The manufacture method of the mask for evaporation disclosed in the present embodiments is also suitable for the manufacture of a mask for evaporation with a special shape, an irregular shape, or a high PPI mask for evaporation.

It should be noted that, referring to FIG. 2d and FIG. 3d again, if a pattern, for example, a photoresist in a ring-shaped region around the hollow portion pattern 7′ of the photoresist layer, of the photoresist layer is removed during the patterning of the photoresist, so that a gap d is formed between the edge of the hollow portion pattern 7′ of the photoresist layer and the side wall h of the open region BB, in the above step S3, the material of the grid structure of the mask for evaporation is also deposited in the gap d, thus a ring structure around the grid structure 7, which may be referred to as “a connecting ring 8” is formed. The existence of the connecting ring 8 connects the edge of the grid structure 7 with the side wall h of the open region BB of the open mask 5, and the three including the connecting ring 8, the grid structure 7, and the open region BB are formed as an integrated structure, so that the combination of the grid structure 7 and the open mask 5 is more firm, and the force uniformity and pixel positional accuracy of the grid structure 7 are further improved.

For example, while removing the photoresist at the non-hollow pattern, for example, at the line position of the grid structure, at least a portion of the photoresist between the edge of the non-hollow portion pattern and the side wall of the opening is removed, so that there may be a gap between the edge of the non-hollow portion pattern and the side wall of the open region.

In the present embodiment, “the material of the non-hollow portion pattern, such as the grid structure, of the mask for evaporation” may be any material that can be used for forming the grid structure of the mask for evaporation, such as invar, a metal nickel (Ni) and the like.

As illustrated in FIG. 2e and FIG. 3e, after the step S3, a step S4 may be further comprised: removing the photoresist layer 6′ to obtain a desired mask for evaporation comprising the non-hollow portion pattern. The photoresist layer 6′ may be removed by stripping, ashing, or the like.

Based on the manufacture method of a mask for evaporation mentioned above, the present embodiment further provides a mask for evaporation, which is manufactured by the above manufacture method, as illustrated in FIG. 2e and FIG. 3e, the mask for evaporation comprises: an open mask 5 having at least one open region BB, and at least one non-hollow portion pattern 7 of the mask for evaporation. The at least one non-hollow portion pattern 7 of the mask for evaporation is in the at least one open region in a one-to-one correspondence, and the non-hollow portion pattern is connected to a side wall h of the open region in which the non-hollow portion pattern is located at an edge of the non-hollow portion pattern.

The non-hollow portion pattern of the mask for evaporation is a grid structure comprising horizontally and vertically intersecting lines.

For example, at least one grid structure 7, such as each grid structure 7, is provided in each of the open regions BB in a one-to-one correspondence, and the edge of the grid structure 7 is connected to the side wall h of the open region BB where the grid structure is located to form an integrated structure.

In the above mask for evaporation, because the grid structure 7 is formed by directly depositing the material of the grid structure in the open region BB of the open mask 5, the grid structure 7 and the side wall h of the open region BB are formed to an integrated structure. Therefore, the force uniformity on the grid structure 7 is relatively excellent, no wrinkle is formed in the display region, and the pixel positional accuracy is high, so that the problem of color mixing of the evaporated light emitting layers can be effectively prevented.

For example, an area of the non-hollow portion pattern of the mask for evaporation is smaller than an area of the open region.

For example, a connection structure is disposed between at least a portion of the edge of the mask for evaporation and the side wall of the opening, the connection structure connects the edge and the side wall.

For example, the mask for evaporation further comprises a connection structure, such as a connecting ring 8, between the side wall h of the open region BB and the edge of the grid structure 7, and the side wall h of the open region BB is connected with the edge of the grid structure 7 by the connecting ring 8. The three including the connecting ring 8, the grid structure 7, and the open region BB are formed as an integrated structure, so that the grid structure 7 can be firmly fixed in the open region BB of the open mask 5, and the force uniformity and pixel positional accuracy of the grid structure 7 are further improved.

As a possible design, a width of the connection structure may range from 0.1 mm to 20 mm.

In the above mask for evaporation, the material of the open mask 5, the grid structure 7, and the connection structure 8 may include any material that can be used for forming the mask for evaporation, such as invar, metal nickel or the like.

In addition, thicknesses of the grid structure 7 and the connecting ring 8 may be equal to or smaller than the thickness of the open mask 5, which is not limited by the embodiment.

In the embodiment, the grid structure 7 and the connecting ring 8 may be directly formed in the opening region BB of the open mask 5 by an electroforming deposition process, so that the grid structure 7, the connecting ring 8, and the open mask 5 are directly formed to an integrated structure.

The mask for evaporation in the embodiments may further comprise: a support frame 11 disposed on a side of the open mask 5 (for example, a side of the open mask 5 away from the substrate to be evaporated), the support frame 11 is connected with a side of the open mask 5, so as to support the open mask 5 to enhance the entire mechanical strength of the mask for evaporation. For example, the support frame 11 may be a metal frame.

In the manufacture method of a mask for evaporation and the mask for evaporation provided by the embodiments of the present disclosure, a photoresist layer comprising a hollow portion pattern corresponding to the non-hollow portion pattern of a mask for evaporation is formed in an open region of the open mask, then, the non-hollow portion pattern of the mask for evaporation is directly formed by depositing the material of the mask for evaporation, and the formed non-hollow portion pattern, such as the grid structure, of the mask for evaporation is naturally connected to the opening of the open mask. Therefore, a tensioning process for the non-hollow portion pattern, such as the FMM unit of grid structure, of the mask for evaporation is avoided, and the problem of uneven force on the non-hollow portion pattern, such as the grid structure, of the mask for evaporation caused by the tensioning process is avoided, so that the force on each portion of the non-hollow portion pattern, such as the grid structure, of the formed mask for evaporation is uniform, and no wrinkle is generated in the display region of the mask for evaporation, or the wrinkle is alleviated, and the pixel positional accuracy of the grid structure of the mask for evaporation is improved, and the quality of the mask for evaporation is improved, which is beneficial to the quality of the evaporated light emitting layers.

The above descriptions are only specific embodiments of the present disclosure, but the protection scope of the present disclosure is not limited thereto, those skilled in the art may make some improvements and modifications within the technical scope of the present disclosure, and the improvements and modifications should be within the protection scope of the present disclosure. Therefore, the protection scope of the present disclosure should be determined by the protection scope of the claims.

In the descriptions of the present specification, the terms “one embodiment”, “some embodiments”, “example”, “specific example”, or “some examples” and the like mean a specific feature, structure, material, or characteristic described in the embodiment or example is included in at least one embodiment or example of the present disclosure. In the present specification, the schematic illustration of the above terms is not necessarily directed to the same embodiment or example. Furthermore, the described particular features, structures, materials, or characteristics may be combined in a suitable manner in any one or more embodiments or examples. In addition, in case of no conflict, features in different embodiments or examples or different embodiments or examples of the present specification may be combined by those skilled in the art.

Moreover, the terms “first” and “second” are used for descriptive purposes only and are not to be construed as indicating or implying a relative importance or implicitly indicating the number of technical features indicated. Thus, features defined “first” or “second” may include at least one of the features, either explicitly or implicitly. In the description of the present disclosure, the meaning of “a plurality” is two or more unless specifically defined otherwise.

Any process or method description in the flowcharts or other described methods may be understood to comprise one or more modules, segments or portions of codes of executable instructions that are used for implementing the step of a particular logical function or process. The scope of the preferred embodiments of the disclosure includes additional implementations, which may not according to the illustrated or discussed order, and performs the functions according to a substantially simultaneous order or in an opposite order of the functions involved, which is understood by those skilled in the art of the embodiments of the present disclosure.

The logic and/or steps described in the flowchart or otherwise described method, for example, may be considered as an ordered list of executable instructions for implementing logical functions, and may be embodied in any computer readable medium, so as to be used in an instruction execution system, apparatus, or device (for example, a computer-based system, a system including a processor, or other systems that can obtain instructions from an instruction execution system, apparatus, or device and execute instructions), or used in combination with the instruction execution system, apparatus, or device. For the specification, the “computer-readable medium” can be any apparatus that can contain, store, communicate, propagate, or transport a program for an instruction execution system, apparatus, or device, or be used by being combined with the instruction execution system, apparatus, or device. More specific examples (non-exhaustive list) of computer readable media comprise the following: electrical connections (electronic devices) having one or more wires, portable computer disk cartridges (magnetic devices), random access memory (RAM), read only memory (ROM), erasable editable read only memory (EPROM or flash memory), fiber optic devices, and portable compact disk read only memory (CDROM). In addition, the computer readable medium may even be a paper or other suitable medium on which the program can be printed, because the paper or other suitable medium may be optically scanned, and followed by editing, interpretation and other appropriate method, the programs can be obtained by electronical method and then stored in the computer memory.

It should be understood that portions of the present disclosure may be implemented by hardware, software, firmware or a combination thereof. In the above embodiments, multiple steps or methods may be implemented in software or firmware stored in a memory and executed by a suitable instruction execution system. For example, where the hardware is used to implement the present disclosure, as in another embodiment, it can be implemented by any one or combination of the following techniques well known in the art: discrete logic circuits comprising logic gates for implementing logic functions on data signals, application specific integrated circuits with suitable combinational logic gates, programmable gate arrays (PGAs), field programmable gate arrays (FPGAs), and so on.

Those skilled in the art can understand that all or part of the steps in the method of implementing the above embodiments can be completed by a program to instruct a related hardware, and the program can be stored in a computer readable storage medium. Where the program is executed, one or a combination of the steps of the method embodiments is included.

In addition, each functional unit in each embodiment of the present disclosure may be integrated into one processing module, or each unit may exist physically separately, or two or more units may be integrated into one module. The above integrated modules can be implemented in a form of hardware or in a form of software functional module. The integrated module may also be stored in a computer readable storage medium, if the integrated module is implemented in the form of software functional module and sold or used as an independent product.

The above storage medium may be a read only memory, a magnetic disk, an optical disk or the like. Although the embodiments of the present disclosure have been shown and described, it is understood that the above embodiments are illustrative and are not to be construed as limiting of the scope of the present disclosure. The embodiments can be changed, modified, substituted and varied within the scope of the present disclosure by those skilled in the art.

The present application claims priority of Chinese patent application No. 201810547816.4, filed on May 31, 2018, the disclosure of which is incorporated herein by reference as part of the application.

1. A manufacture method of a mask for evaporation, comprising:
providing an open mask, the open mask comprising at least one open region;
forming a photoresist layer at least in the at least one open region, at least a portion of a pattern of the photoresist layer in the open region being identical to a hollow portion pattern of the mask for evaporation; and
depositing a material of the mask for evaporation in the open region in which the photoresist layer is formed, so as to form a non-hollow portion pattern of the mask for evaporation, wherein the non-hollow portion pattern is connected to a side wall of the open region at an edge of the non-hollow portion pattern.

2. The manufacture method of a mask for evaporation according to claim 1, further comprising:
removing the photoresist layer, so as to obtain the mask for evaporation comprising the non-hollow portion pattern.

3. The manufacture method of a mask for evaporation according to claim 1, wherein depositing of the material of the mask for evaporation on a side of the open mask in which the photoresist layer is formed comprises:
depositing the material of the mask for evaporation by an electroforming deposition process.

4. The manufacture method of a mask for evaporation according to claim 1, wherein the forming of the photoresist layer in the at least one open region comprises:
coating a photoresist in the at least one open region;
patterning the photoresist, to remove the photoresist at a line position of the non-hollow portion pattern.

5. The manufacture method of a mask for evaporation according to claim 4, wherein an area of the non-hollow portion pattern of the mask for evaporation is smaller than an area of the open region.

6. The manufacture method of a mask for evaporation according to claim 5, further comprising:
further removing at least a portion of the photoresist between the edge of the non-hollow portion pattern and the side wall of the open region while removing the photoresist at the line position of the non-hollow portion pattern, so that a gap is formed between a portion of the pattern of the photoresist layer corresponding to the at least a portion of the edge of the non-hollow portion pattern and the side wall of the open region.

7. The manufacture method of a mask for evaporation according to claim 6, wherein the further removing of at least a portion of the photoresist between the edge of the non-hollow portion pattern and the side wall of the open region while removing the photoresist at the line position of the non-hollow portion pattern comprises:
removing an annular photoresist between the edge of the non-hollow portion pattern and the side wall of the open region, so that a gap is formed between the pattern of the photoresist layer corresponding to the edge of the non-hollow portion pattern and the side wall of the open region.

8. The manufacture method of a mask for evaporation according to claim 1, wherein a thickness of the photoresist layer is equal to a thickness of the open mask; or
a thickness of the photoresist layer is smaller than a thickness of the open mask, and one surface of the photoresist layer is flush with one surface of the open mask.

9. The manufacture method of a mask for evaporation according to claim 1, wherein the photoresist layer further covers a non-open region of the open mask.

10. The manufacture method of a mask for evaporation according to claim 1, wherein before the forming of a photoresist layer in the at least one open region, the method comprises: placing the open mask on a base, so as to allow the base to support the open region.

11. (canceled)

12. The manufacture method of a mask for evaporation according to claim 1, wherein under a condition that the photoresist layer is formed only in the at least one open region, the depositing of a material of the mask for evaporation in a region in which the photoresist layer is formed comprises:
blocking the non-open region, so as to deposit the material of the mask for evaporation in the region in which the photoresist layer is formed.

13. A mask for evaporation, the mask for evaporation being manufactured by the manufacture method according to claim 1, and the mask for evaporation comprising:
an open mask, comprising at least one open region; and
at least one non-hollow portion pattern of the mask for evaporation, wherein the at least one non-hollow portion pattern of the mask for evaporation is in the at least one open region in a one-to-one correspondence, and the non-hollow portion pattern is connected to a side wall of the open region in which the non-hollow portion pattern is located at an edge of the non-hollow portion pattern.

14. The mask for evaporation according to claim 13, wherein an area of the non-hollow portion pattern of the mask for evaporation is smaller than an area of the open region.

15. The mask for evaporation according to claim 14, wherein a connection structure is disposed between at least a portion of the edge of the non-hollow portion pattern of the mask for evaporation and the side wall of the open region, and the connection structure connects the edge of the non-hollow portion pattern of the mask for evaporation and the side wall of the open region.

16. The mask for evaporation according to claim 15, wherein an annular connection structure is disposed between the edge of the non-hollow portion pattern of the mask for evaporation and the side wall of the open region, the annular connection structure is around the non-hollow portion pattern of the mask for evaporation.

17. The mask for evaporation according to claim 15, wherein a width of the connection structure ranges from 0.1 mm to 20 mm, materials of the open mask, the non-hollow portion pattern, and the connection structure comprise invar and/or metal nickel.

18. (canceled)

19. The mask for evaporation according to claim 15, wherein thicknesses of the non-hollow portion pattern and the connection structure are equal to or smaller than a thickness of the open mask.

20. The mask for evaporation according to claim 13, wherein the non-hollow portion pattern of the mask for evaporation is a grid structure comprising horizontally and vertically intersecting lines.

21. The mask for evaporation according to claim 13, wherein the mask for evaporation further comprises: a support frame at a side of the open mask, the support frame being in contact with a side of the open mask, so as to support the open mask.

22. The mask for evaporation according to claim 15, wherein the open mask, the connection structure, and the non-hollow portion pattern of the mask for evaporation form as an integrated structure.
